(19) United States
(12) Patent Application Publication
(10) Pub. No.: US 2025/0266287 A1
(43) Pub. Date: Aug. 21, 2025

(54) SUSCEPTOR IMPROVEMENT

(71) Applicant: Applied Materials, Inc., Santa Clara, CA (US)

(72) Inventors: Hui CHEN, Tempe, AZ (US); Papo CHEN, San Jose, CA (US); Xinning LUAN, Tempe, AZ (US); Shawn THOMAS, Chesterfield, MO (US)

(21) Appl. No.: 19/034,193

(22) Filed: Jan. 22, 2025

Related U.S. Application Data
(60) Provisional application No. 63/555,479, filed on Feb. 20, 2024.

(51) Int. Cl. H01L 21/687; C23C 16/458; C30B 25/12

(52) U.S. Cl. CPC H01L 21/68785; C23C 16/4584; C30B 25/12; H01L 21/68735

(57) ABSTRACT

A susceptor for a processing chamber is provided including: an inner portion having a center; an outer rim disposed around the inner portion, the outer rim including a first inner side surface and a first outer side surface; and a plurality of apertures, each aperture extending from the first outer side surface to the first inner side surface. Each aperture of the plurality of apertures is located at a different angular location relative to the center of the inner portion.

### CROSS-REFERENCE TO RELATED APPLICATIONS

This application claims benefit of U.S. provisional patent application Ser. No. 63/555,479, filed Feb. 20, 2024, which is hereby incorporated herein by reference.

### BACKGROUND

### Field

Embodiments of the present disclosure generally relate to susceptors for use in processing of substrates (e.g., semiconductor substrates), and more particularly to susceptors having features to improve process uniformity across a substrate during processing.

### Description of the Related Art

Susceptors are often used in epitaxy processes to support a substrate as well as to heat the substrate to a highly uniform temperature. Susceptors often have platter or dish-shaped upper surfaces that are used to support a substrate from below around the edge(s) of the substrate while leaving a small gap between the remaining lower surface of the substrate and the upper surface of the susceptor. Precise control over a heating source, such as a plurality of heating lamps disposed below the susceptor, allows a susceptor to be heated within very strict tolerances. The heated susceptor can then transfer heat to the substrate, primarily by radiation emitted by the susceptor.

Despite the precise control of heating the susceptor in epitaxy, temperature non-uniformities persist across the upper surface of the substrate often reducing the quality of the process (e.g., deposition) being performed on the substrate. For example, the deposition rate near the edge of the substrate can be different than for other portions of the substrate. Furthermore, deposition rates can also vary in different crystallographic directions, which can also add to deposition thickness non-uniformities across the substrate. Therefore, an ongoing need exists for addressing non-uniformities.

### SUMMARY

Embodiments of the present disclosure generally relate to susceptors for use in processing of substrates (e.g., semiconductor substrates), and more particularly to susceptors having features to improve process uniformity across a substrate during processing.

In one embodiment, a susceptor for a processing chamber is provided comprising: an inner portion having a center; an outer rim disposed around the inner portion, the outer rim including a first inner side surface and a first outer side surface; and a plurality of apertures, each aperture extending from the first outer side surface to the first inner side surface, wherein each aperture of the plurality of apertures is located at a different angular location relative to the center of the inner portion.

In another embodiment, a process chamber is provided comprising: a chamber body disposed around an interior volume; a substrate support assembly comprising: a shaft and a susceptor configured to be rotated by the shaft, the susceptor disposed in the interior volume and comprising: an inner portion having a center; an outer rim disposed around the inner portion, the outer rim including a first inner side surface and a first outer side surface; and a plurality of apertures, each aperture extending from the first outer side surface to the first inner side surface, wherein each aperture of the plurality of apertures is located at a different angular location relative to the center of the inner portion.

In another embodiment, a method of processing a substrate is provided comprising: positioning a substrate on a susceptor in an interior volume of a process chamber, the susceptor comprising: an inner portion having a center; an outer rim disposed around the inner portion, the outer rim including a first inner side surface and a first outer side surface; and a plurality of apertures, each aperture extending from the first outer side surface to the first inner side surface, wherein each aperture of the plurality of apertures is located at a different angular location relative to the center of the inner portion; and performing a first process on the substrate by providing one or more process gases to the interior volume of the process chamber while rotating the susceptor to deposit a layer on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a cross-sectional view of a processing system, according to one embodiment.

FIG. 2A is a top view of the susceptor from FIG. 1, according to one embodiment.

FIG. 2B is a side cross-sectional view of the susceptor taken along section line 2B of FIG. 2A, according to one embodiment.

FIG. 2C is a side cross-sectional view of the susceptor taken along section line 2C of FIG. 2A, according to one embodiment.

FIG. 3A is a top view of a susceptor, according to one embodiment.

FIG. 3B is a top view of a substrate positioned on the susceptor, according to one embodiment.

FIG. 4 is a process flow diagram of a method for processing a substrate, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to susceptors and related methods for use in processing of substrates (e.g., semiconductor substrates), and more particularly to susceptors having features to improve process uniformity across a substrate during processing. The susceptors disclosed herein can improve the uniformity of the process being performed on the substrate supported by the susceptor by improving the gas flow over the substrate during processing. The susceptor can include a plurality of apertures that extend through an outer component of the susceptor, such as an outer rim of the susceptor. Each aperture of the plurality of apertures directs the gas along a gas flow path through the outer component and over an inner portion of the susceptor. The substrate is supported over the inner portion of the susceptor during processing, so the gas directed through the plurality of apertures flows along a gas flow path over the substrate during processing. Flowing at least some of the gas through the plurality of apertures in the outer component of the susceptor during processing can increase the concentrations of gas and/or residence time of the gases over the edge regions of the substrate relative to otherwise similar processes performed on the susceptors lacking the plurality of apertures in the outer component.

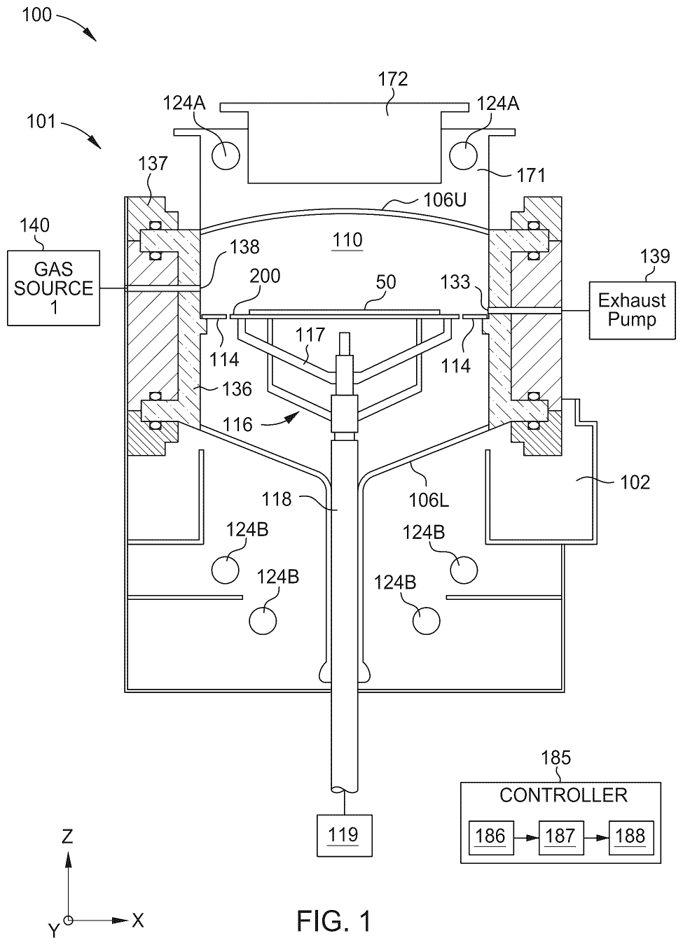

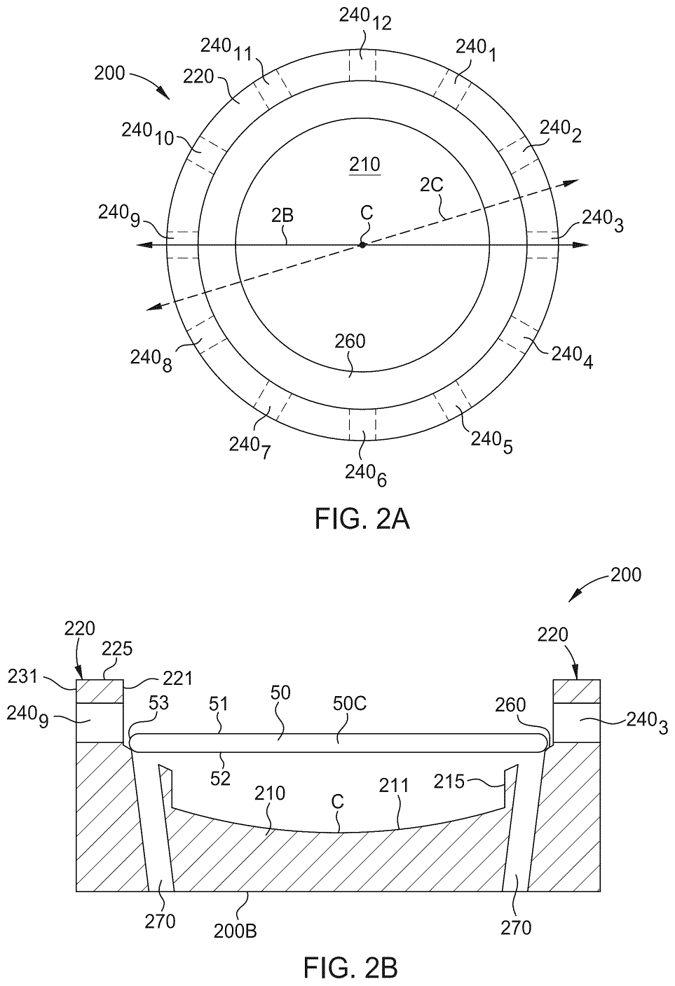

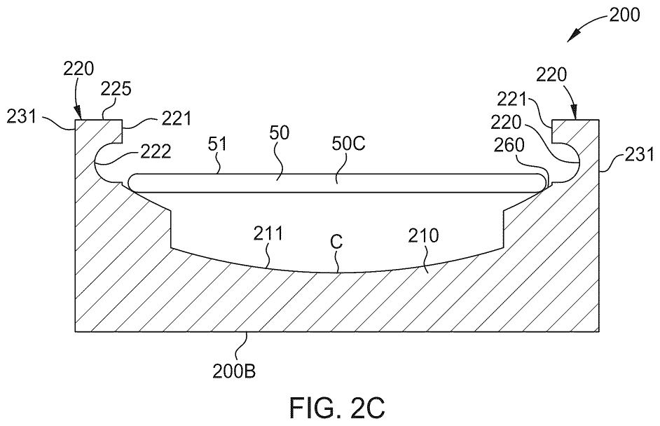

These increased concentrations and/or residence times of the gases can be used to improve the uniformity (e.g., deposition thickness uniformity) of the process being performed, especially in situations in which the process rate (e.g., deposition rate) is slower at the edge of the substrate than the corresponding process rate at the center of the substrate when a conventional susceptor is used. The residence time of gases over different portions of the substrate (e.g., edge versus center) can be more challenging in process chambers using a cross-flow path over the substrate (e.g., a substantially horizontal path), such as the epitaxial deposition chamber described below in FIG. 1, when compared to process chambers that provide gas to the interior volume using a component disposed over the substrate, such as a showerhead. The susceptors disclosed herein can be used to overcome these challenges relating to gas concentration and residence time uniformity. Furthermore, in some embodiments (see FIG. 2C), the outer component (e.g., outer rim) of the susceptor can include a recessed region to increase the volume of space near the edge of the substrate during processing, which can also improve process uniformity.

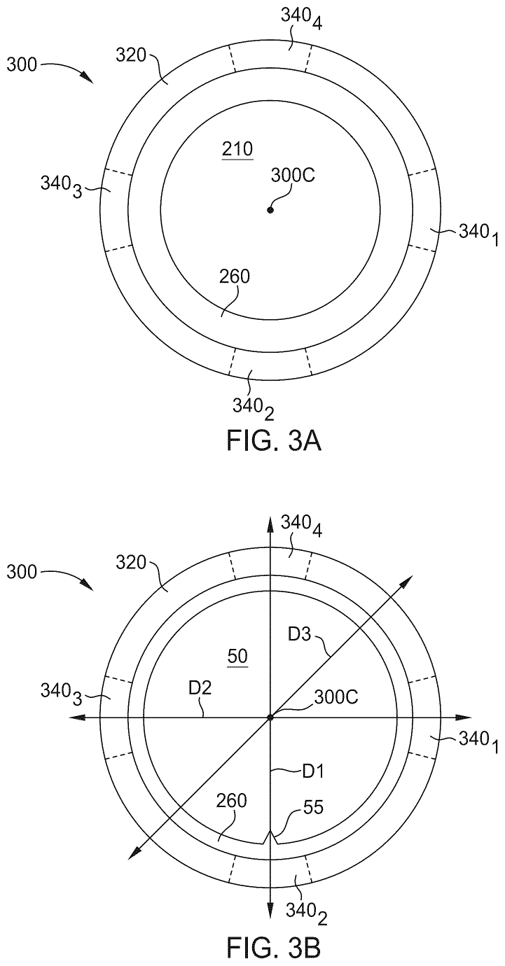

The susceptors disclosed herein can also be used to reduce non-uniformities for deposition growth rates in different crystallographic directions. For example, in some embodiments (see e.g., FIGS. 3A and 3B), the susceptor disclosed herein can be used to reduce non-uniformities between the growth rate in the <100> direction and the growth rate in the <110> direction. Reducing non-uniformities for growth rates in different crystallographic directions improves the uniformity of the process being performed (e.g., the layer being deposited on the substrate) and eventually leads to an improved end product.

Although the following describes the benefits of this disclosure in reference to an epitaxial deposition process, the benefits of this disclosure can more generally be applied to any process that uses a susceptor or substrate support having an outer component (e.g., an outer rim) disposed around an inner component (e.g., an inner portion).

FIG. 1 is a cross-sectional view of a processing system 100, according to one embodiment. The processing system 100 includes a process chamber 101, a gas supply source 140, an exhaust pump 139, and a controller 185. The processing system 100 can be configured to perform epitaxial deposition processes in the process chamber 101 as well as other processes, such as cleaning processes.

The process chamber 101 includes a chamber body 102. In some embodiments, the chamber body 102 can be made of a process resistant material, such as aluminum or stainless steel, for example 316L stainless steel. The chamber body 102 is disposed around structural components of the process chamber 101, such as an upper window 106U, a lower window 106L, an inner liner 136, and an outer liner 137. In one embodiment, the windows 106U, 106L can each be formed of quartz. The liners 136, 137 can be positioned between the windows 106U, 106L and the chamber body 102 to insulate the windows 106U, 106L from the chamber body 102. The windows 106U, 106L and the liners 136, 137 enclose an interior volume 110 (also referred to as process volume) of the process chamber 101. The process chamber 101 can further include a gas inlet 138 extending through the liners 136, 137 to provide a gas flow path into the interior volume 110 from outside of process chamber 101.

The process chamber 101 includes a substrate support assembly 116. The substrate support assembly 116 can include supports 117 and a shaft 118. A susceptor 200 can be positioned on the supports 117. A substrate 50 is positioned on the susceptor 200. A simplified illustration of the susceptor 200 is shown in FIG. 1. Additional detail on the susceptor 200 is shown in FIGS. 2A-2C. An alternative susceptor 300 is described below in reference to FIGS. 3A and 3B. The substrate support assembly 116 can further include an actuator 119 to rotate the shaft 118, the susceptor 200, and substrate 50 during processing, such as during an epitaxial deposition.

Gases can be introduced into the interior volume 110 from the gas supply source 140 during depositions, cleaning, or other processes. These gases can be exhausted from the interior volume 110 through an exhaust outlet 133 by the exhaust pump 139. The process chamber 101 can further include a preheat ring 114 that can be positioned around the susceptor 115.

The process chamber 101 can further include upper lamp modules 124A and lower lamp modules 124B for heating of the substrate 50 and/or the interior volume 110. In one embodiment, the upper lamp modules 124A and the lower lamp modules 124B are infrared (IR) lamps.

The process chamber 101 further includes an outer reflector 171 and an inner reflector 172 positioned over the upper window 106U. The outer reflector 171 can be positioned around the inner reflector 172. In some embodiments one or more upper lamp modules 124A can be positioned inside the outer reflector 171.

The processing system 100 also includes the controller 185 for controlling processes performed by the processing system 100. The controller 185 can be any type of controller used in an industrial setting, such as a programmable logic controller (PLC). The controller 185 includes a processor 187, a memory 186, and input/output (I/O) circuits 188. The controller 185 can further include one or more of the following components (not shown), such as one or more power supplies, clocks, communication components (e.g., network interface card), and user interfaces typically found in controllers for semiconductor equipment.

The memory 186 can include non-transitory memory. The non-transitory memory can be used to store the programs and settings described below. The memory 186 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

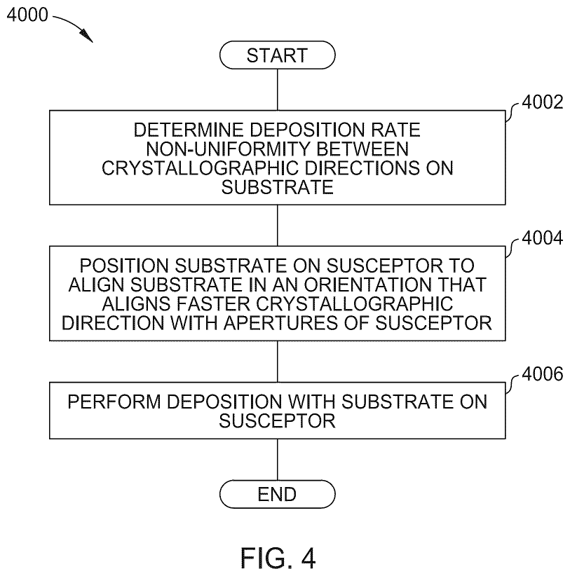

The processor 187 is configured to execute various programs stored in the memory 186, such as epitaxial deposition processes and purging processes. As one example, the controller 185 can be used to execute a program stored in the memory 186 to perform many of the operations described below in reference to FIG. 4. During execution of these programs, the controller 185 can communicate to I/O devices through the I/O circuits 188. For example, during execution of these programs and communication through the I/O circuits 188, the controller 185 can control outputs, such as the position of valves to send process gases to the interior volume 110 of the process chamber 101 or to perform purging processes. The memory 186 can further include various operational settings used to control the processing system 100. For example, the settings can include durations for how long the different valves remain open or closed during different depositions and purging processes.

FIG. 2A is a top view of the susceptor 200 from FIG. 1, according to one embodiment. FIG. 2B is a side cross-sectional view of the susceptor 200 taken along section line 2B of FIG. 2A, according to one embodiment. The following paragraphs describe the susceptor 200 with reference to FIGS. 2A and 2B.

The susceptor 200 includes an inner portion 210 and an outer rim 220 that is disposed around the inner portion 210. In some embodiments, the inner portion 210 can be referred to as inner dish or inner pocket, but a dish shape or pocket shape is not required. In some embodiments, the outer rim 220 fully surrounds the inner portion 210. The inner portion 210 includes a first surface 211 that is configured to face the bottom of the substrate 50 during processing. The first surface 211 can include a center C, which is also referred to as the center C of the susceptor 200. In some embodiments, the first surface 211 can have a concave profile, for example as shown, with the center C of first surface 211 spaced further apart from the substrate 50 during processing than outer regions of the first surface 211 are spaced apart from the substrate 50. A center 50C of the substrate 50 can overlie the center C of the top surface 211 of the inner portion 210. The inner portion 210 can further include an outer wall 215 extending above the first surface 211. The substrate 50 includes a top surface 51 (first surface), a bottom surface 52 (second surface), and one or more sides 53 connecting the top surface 51 with the bottom surface 52.

The outer rim 220 can include a first inner side surface 221 and a first outer side surface 231. The outer rim 220 can further include a top surface 225 connecting the first inner side surface 221 with the first outer side surface 231. In some embodiments, the susceptor can include one or more additional surfaces (not shown) that can connect the first inner side surface 221 with the first outer side surface 231.

The susceptor 200 further includes a supporting structure 260 that connects the inner portion 210 to the outer rim 220. The substrate 50 can be positioned on the supporting structure 260 during processing. Only a portion of the bottom surface 52 of the substrate 50 near the one or more sides 53 of the substrate 50 is positioned on the supporting structure 260 during processing, so that the vast majority of the bottom surface 52 of the substrate 50 does not contact the susceptor 200 during processing. The supporting structure 260 is shown as an angled surface in FIG. 2B, but other structures can also be used, such as an annular ridge extending upward and around the inner portion 210 at substantially the same location as the angled surface shown in FIG. 2B. The angled surface of the supporting structure 260 can extend downwardly from the outer rim 220 to the inner portion 210.

The susceptor 200 further includes a plurality of apertures 240 with each aperture 240 extending through the outer rim 220 from the first outer side surface 231 to the first inner side surface 221. Each aperture 240 can be located above the inner portion 210. Each aperture 240 can also be located above the supporting structure 260. The apertures 240 can each be configured to provide a gas flow path for some of the gases provided to the interior volume 110 to flow through the apertures 240 and over the inner portion 210 and the top surface 51 of the substrate 50 during processing. More generally, each aperture 240 can be configured to provide a gas flow path for directing gas from a first location outside the outer rim 220 to a second location inside the outer rim 220 and over the inner portion 210. Apertures that can direct gas from outside the outer rim of a susceptor to a location inside the outer rim and over an inner portion of the susceptor can help improve the process uniformity of the process (e.g., deposition) being performed on a substrate supported by the susceptor because these apertures improve the uniformity of the gas concentrations over the substrate during processing, such as center to edge gas concentration uniformity. Other gases provided to the interior volume 110 can flow over the top surface 225 of the outer rim 220 before reaching the region of the interior volume 110 overlying the top surface 51 of the substrate 50, which is the only gas flow path for processes performed using conventional susceptors.

The susceptor 200 is shown as including twelve apertures 240₁-240₁₂, but other embodiments can include more or fewer apertures 240. In some embodiments, for example as shown in FIG. 2B, each aperture 240 of the plurality of apertures 240 can be located at a different angular location relative to the center C of the inner portion 210. However, in other embodiments (not shown), two or more apertures can have a same angular location, such as a first aperture overlying a second aperture. As described above in reference to FIG. 1, the substrate support assembly 116 can further include the actuator 119 configured to rotate the susceptor 200 during processing. This rotation can allow each of the apertures 240 to be rotated to a position facing the gas inlet 138 during processing, so that the gas flowrates through each of the apertures 240 during processing is substantially the same.

The plurality of apertures 240 can increase the uniformity of the concentration of gases and residence times for the gases over the top surface 51 of substrate 50, so that there is less variation between concentration and residence times of the gases over the center 50C of the substrate 50 relative to the edge of the substrate 50 near the one or more side surfaces 53. By improving the uniformity of the concentration and residence times of the gases over the entire top surface 51 of the substrate 50, the uniformity (e.g., deposition thickness uniformity) of the corresponding process can also be improved. For example, using the susceptor 200 having the plurality of apertures 240 during process can improve deposition thickness uniformity on the top surface 51 of the substrate during an epitaxial deposition performed in the process chamber 101 (see FIG. 1) compared to the same process performed on an otherwise similar susceptor that does not include the apertures 240.

In some embodiments, the susceptor 200 can include a plurality of channels 270, each channel 270 extending from a first opening between the supporting structure 260 and the outer wall 215 of the inner portion 210 to a second opening at a bottom 200B of the susceptor 200. The plurality of channels 270 can be used to remove any gases that reach the region of the interior volume 110 between the bottom surface 52 of the substrate 50 and a portion of the susceptor 200, so that unintended processes (e.g., backside deposits) on the substrate 50 can be prevented.

FIG. 2C is a side cross-sectional view of the susceptor 200 taken along section line 2C of FIG. 2A, according to one embodiment. The view in FIG. 2C shows the cross-sectional view of the susceptor 200 at locations other than locations including one or more of the apertures 240. In some embodiments, the outer rim 220 can additionally include a second inner side surface 222 below the first inner side surface 221. The first inner side surface 221 can be located more inwardly towards the center C of the susceptor 200 relative to the second inner side surface 222. The second inner side surface 222 can curve outwardly away from the first inner side surface 221 and then curve inwardly to the angled surface of the supporting structure 260. In some embodiments, for example as shown in FIG. 2C, the second inner side surface 222 can have a concave profile. In one embodiment, the second inner side surface 222 can have a C-shaped profile. The outwardly extending second inner side surface 222 can be used to increase the volume available for the process gases inside the outer rim 220 of the susceptor 200 above the top surface 51 of the substrate 50. In some embodiments, this increase in volume can improve process uniformity (e.g., deposition thickness uniformity) for the edge of the substrate 50 relative to the center 50C of the substrate 50.

FIG. 3A is a top view of a susceptor 300, according to one embodiment. The susceptor 300 includes the same inner portion 210 and supporting structure 260 that were included in the susceptor 200. The susceptor 300 is substantially similar to the susceptor 200 described above except that the susceptor 300 includes an outer rim 320 that is different than the outer rim 220 of the susceptor 200. The outer rim 320 of the susceptor 300 includes four apertures 340₁-340₄. The apertures 340 are similar to the apertures 240 described above except that the apertures 340 are larger and there are only four apertures 340 instead of the twelve apertures 240. Each aperture 340 is positioned at an angular location that is 90 degrees apart from another aperture 340 when the angular location is determined relative to a center 300C of the susceptor 300.

FIG. 3B is a top view of a substrate 50 positioned on the susceptor 300, according to one embodiment. The susceptor 300 can be used in the process chamber 101 of FIG. 1 instead of the susceptor 200 described above. The substrate 50 is the same as the substrate 50 described above except that the substrate 50 includes an alignment feature 55 that can assist with aligning the substrate 50 on the susceptor 300. The alignment feature 55 is shown as a notch, but other alignment features (e.g., a mark) can also be used to align the substrate on the susceptor 300.

Processes performed on substrates can often vary in different crystallographic directions. For example, on the substrate 50, the deposition rate in the <100> direction is faster than the deposition rate in the <110> direction. In this example, the alignment feature 55 and the center 300C of the substrate 50 are used as reference points for determining crystallographic directions. Using these reference points, the <100> direction is represented by directions D1 and D2, and the <110> direction is represented by the direction D3. Another example of the <110> direction could be represented by another line that is orthogonal to the D3 direction, but this is not shown in order to not clutter the drawing.

The substrate 50 is positioned on the substrate 50 with the alignment feature 55 aligned with the D1 direction (i.e., one of the <100> directions). When gas is provided through the apertures 340 during processing as the susceptor 300 is rotated, the deposition rates in the <110> directions become more uniform with the deposition rates in the <100> directions.

FIG. 4 is a process flow diagram of a method 4000 for processing a substrate, according to one embodiment. The method 4000 can be used to deposit a layer on the substrate. The method 4000 can also be used to improve the process uniformity of a deposition on a substrate for a process that would otherwise have non-uniformities in different crystallographic directions. The method 4000 can be performed in part by the controller 185 from FIG. 1. Although the method 4000 is described as being performed on the susceptor 300 from FIGS. 3A, 3B to improve uniformity in different crystallographic directions, a substantially similar method can also be performed on the susceptor 200 to improve center to edge deposition uniformity. Furthermore, performing a deposition on the susceptor 300 can improve center to edge deposition uniformity in a similar manner as the susceptor 200.

The method begins at block 4002. At block 4002, it is determined that a deposition performed on a substrate with a conventional susceptor has a deposition growth rate non-uniformity between the crystallographic directions <100> and <110>.

At block 4004, the substrate 50 including the alignment feature 55 is transferred into the process chamber 101 (see FIG. 1) and positioned on the susceptor 300 as shown in FIG. 3B with the alignment feature 55 aligned with a center of one of the apertures 340. The alignment feature 55 is aligned with the <100> crystallographic direction D1, which is the direction that experienced a higher deposition rate compared to the <110> when the otherwise similar deposition was performed on a conventional susceptor. Each of the apertures 340₁-340₄ are aligned with the <100> crystallographic directions D1 and D2. The position of the substrate 50 on the susceptor 300 also causes the <110> crystallographic directions to be aligned at angular locations corresponding to the midpoint angular locations between neighboring apertures 340.

At block 4006, the deposition is performed on the substrate 50 that is positioned on the susceptor 300 in the process chamber 101 (see FIG. 1). The susceptor 300 and the substrate 50 are rotated by the actuator 119 during the deposition. Process gases are provided to the interior volume 110 during the deposition. Some of the process gases provided to the interior volume 110 flow through the apertures 340 during the deposition. By aligning the apertures 340 with the alignment feature 55, the uniformity of the deposition rates between the crystallographic directions <100> and <110> is improved when compared to the same deposition performed on a conventional susceptor. After block 4006, the method 4000 ends.

While the foregoing is directed to embodiments of the present disclosure, other and further embodiments of the disclosure may be devised without departing from the basic scope thereof.

What is claimed is:

1. A susceptor for a processing chamber comprising:
an inner portion having a center;
an outer rim disposed around the inner portion, the outer rim including a first inner side surface and a first outer side surface; and
a plurality of apertures, each aperture extending from the first outer side surface to the first inner side surface, wherein each aperture of the plurality of apertures is located at a different angular location relative to the center of the inner portion.

2. The susceptor of claim 1, wherein each aperture of the plurality of apertures is located above the inner portion.

3. The susceptor of claim 1, further comprising a supporting structure that connects the inner portion to the outer rim.

4. The susceptor of claim 3, wherein the supporting structure is an angled surface.

5. The susceptor of claim 1, wherein each aperture of the plurality of apertures is positioned at an angular location relative to the center of the inner portion that is at a right angle relative to an angular location of another aperture of the plurality of apertures relative to the center of the inner portion.

6. The susceptor of claim 1, wherein each aperture of the plurality of apertures is located 180 degrees apart from another aperture of the plurality of apertures relative to the center of the inner portion.

7. The susceptor of claim 1, wherein the outer rim includes a second inner side surface below the first inner side surface, wherein the first inner side surface extends more inwardly towards the center of the inner portion than the second inner side surface extends towards the center of the inner portion.

8. The susceptor of claim 7, wherein the second inner side surface has a curved concave profile.

9. A process chamber comprising:
a chamber body disposed around an interior volume;
a substrate support assembly comprising:
a shaft and a susceptor configured to be rotated by the shaft, the susceptor disposed in the interior volume and comprising:
an inner portion having a center;
an outer rim disposed around the inner portion, the outer rim including a first inner side surface and a first outer side surface; and
a plurality of apertures, each aperture extending from the first outer side surface to the first inner side surface, wherein each aperture of the plurality of apertures is located at a different angular location relative to the center of the inner portion.

10. The process chamber of claim 9, wherein each aperture of the plurality of apertures is located above the inner portion.

11. The process chamber of claim 9, wherein the susceptor further comprises a supporting structure that connects the inner portion to the outer rim.

12. The process chamber of claim 11, wherein the supporting structure is an angled surface.

13. The process chamber of claim 9, wherein each aperture of the plurality of apertures is positioned at an angular location relative to the center of the inner portion that is at a right angle relative to an angular location of another aperture of the plurality of apertures relative to the center of the inner portion.

14. The process chamber of claim 9, wherein each aperture of the plurality of apertures is located 180 degrees apart from another aperture of the plurality of apertures relative to the center of the inner portion.

15. The process chamber of claim 9, wherein the outer rim includes a second inner side surface below the first inner side surface, wherein the first inner side surface extends more inwardly towards the center of the inner portion than the second inner side surface extends towards the center of the inner portion.

16. A method of processing a substrate comprising:
positioning a substrate on a susceptor in an interior volume of a process chamber, the susceptor comprising:
an inner portion having a center;
an outer rim disposed around the inner portion, the outer rim including a first inner side surface and a first outer side surface; and
a plurality of apertures, each aperture extending from the first outer side surface to the first inner side surface, wherein each aperture of the plurality of apertures is located at a different angular location relative to the center of the inner portion; and
performing a first process on the substrate by providing one or more process gases to the interior volume of the process chamber while rotating the susceptor to deposit a layer on the substrate.

17. The method of claim 16, wherein the susceptor includes four apertures extending through the outer rim, each aperture configured to allow the one or more process gases to flow through the aperture during processing.

18. The method of claim 16, wherein each aperture of the four apertures is positioned at an angular location that is at a right angle relative to another aperture when the angular location is determined relative to a center of the susceptor.

19. The method of claim 18, wherein the four apertures are the only apertures extending through the outer rim that are configured to allow the one or more process gases to flow through the outer rim.

20. The method of claim 16, wherein positioning the substrate on the susceptor further comprises aligning the substrate to have an alignment feature on the substrate be aligned with a center of one of the apertures when the substrate is positioned on the susceptor.
